(19) United States
(12) Patent Application Publication
(10) Pub. No.: US 2008/0100144 A1
(43) Pub. Date: May 1, 2008

(54) Automatic Power-Off Method for an Electronic Device

(76) Inventor: Shoei-Lai Chen, Taipei (TW)

Correspondence Address: HDSL, 4331 STEVENS BATTLE LANE, FAIRFAX, VA, 22033, US

(21) Appl. No.: 11/969,963

(22) Filed: Jan. 7, 2008

Related U.S. Application Data
(63) Continuation-in-part of application No. 11/014,590, filed on Dec. 16, 2004.

(51) Int. Cl. H03K 17/28

(52) U.S. Cl. 307/112

(57) ABSTRACT

A method for an electronic device with pressing keys can automatically turn off power when an undesired operation occurs. A time threshold such as 3 or 5 seconds is set by a user in the electronic device. The method keeps detecting the operations of the keys. A pressing operation will be considered undesired if its duration exceeds the time threshold, and then the electric power will be automatically turned off.

This application is a continuous-in-part application of U.S. patent application Ser. No. 11/014,590, filed on Dec. 16, 2004.

### BACKGROUND OF THE INVENTION

1. Field of the Invention

The present invention relates to a power control of an electronic device, and more particularly to an automatic power-off control of a portable electronic device.

2. Prior Art

With the progress of semiconductor and LCD technologies, the consumer electronic products, such as mobile phones, smart phones, portable computers, digital cameras, personal digital assistances (PDAs) and portable GPSes, have become more and more compact and versatile. Usually, the portable electronic products are easy to be carried in pockets or bags.

The conventional electronic devices generally have an input unit, which usually is a plurality of keys, on the surface thereof for inputting instructions and numbers/letters. The input units are subjected to undesired input resulting from unexpectedly touching or pressing when the input units of the electronic devices are not locked. Once a key of the input unit is unintentionally pressed, unnecessary battery power is consumed. It is possible that a user does not know the battery power has been exhausted because of an unintentional press until he/she prepares to use the device.

On the other side, some conventional electronic devices are also provided with power saving function such as hibernation mode or screen shutdown. The power saving function will be executed when no input or no operation is present for a predetermined time. However, those electronic devices under power saving mode will still be triggered into a normal mode and will consume unnecessary battery power when the input unit thereof is unintentionally operated. Therefore, this approach can not prevent power consumption due to unexpected press.

### SUMMARY OF THE INVENTION

The present invention is to provide an automatic power-off method for an electronic device, which can detect a duration of continuously pressing one key of the input unit and turn off the electronic device when the duration exceeds a user-settable time threshold such as 3 or 5 seconds, so that the unnecessary power consuming resulting from unintentional press can be avoided.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows an outward form of a typically portable electronic device.

FIG. 2 shows a flowchart of the automatic power-off method according to the present invention.

### DETAILED DESCRIPTION OF THE INVENTION

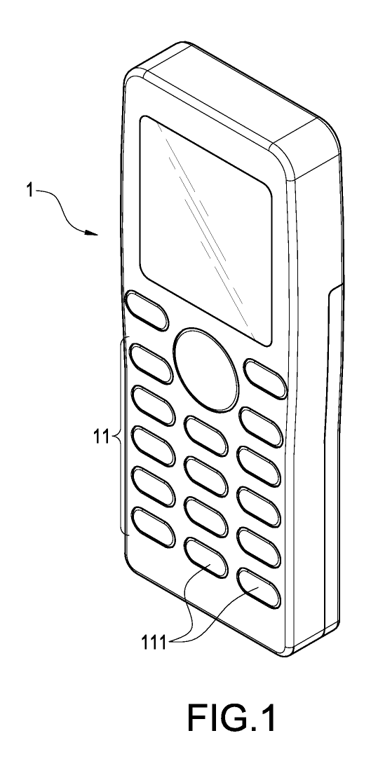

Referring to FIG. 1, a typically portable electronic device is shown. In this preferred embodiment, the electronic device 1 is a mobile phone, but it can be any one of a smart phone, a portable computer, a PDA, a digital camera, etc. The electronic device 1 has an input unit 11 on a surface thereof for inputting command or data. The input unit 11 is composed of a plurality of keys 111.

Under a normal situation, one key 111 will not be continuously pressed over 3 or 5 seconds by a user. However, it is possible that an unexpectedly pressing operation lasts over 3 or 5 seconds due to body motion of the user. Therefore the duration of 3 or 5 seconds can be used as a time threshold for judging that a pressing operation is desired or undesired. If a pressing operation is judged undesired because it exceeds 3 or 5 seconds, the power of the electronic device 1 will be turned off.

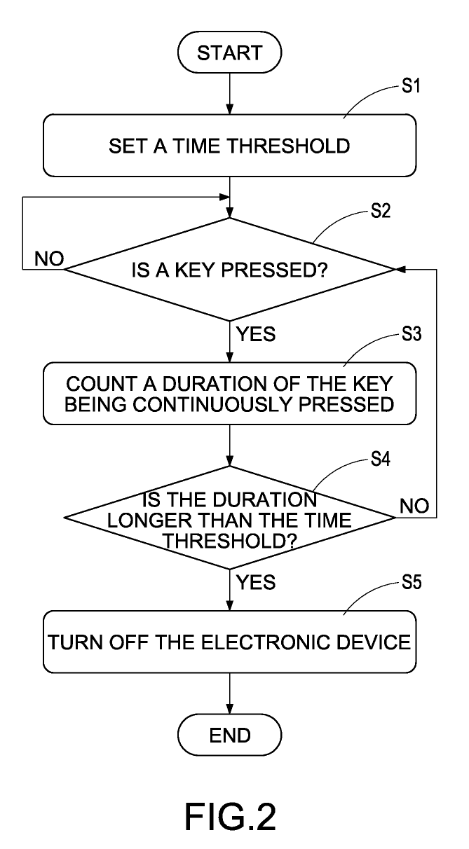

FIG. 2 shows a flowchart of the automatic power-off method according to the present invention. First, in step SI, a time threshold is set by a user of the electronic device 1. The length of the time threshold can be determined by the user, such as 3 or 5 seconds as described above. The time threshold is user-settable. Its length can be freely determined by the user according their various habits or practices. After the time threshold is set, the method keeps detecting whether any one of the keys 111 is pressed in step S2. When a pressing operation is performed to any one of the keys 111, the method will count a length of duration of the key 111 being continuously pressed in step S3. Then, the method compares the duration with the time threshold in step S4. Once the duration of the key 111 being continuously pressed is longer than the time threshold, the pressing operation is judged undesired and the method will automatically turn off the power of the electronic device 1 for saving unnecessary power consuming in step S5.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. An automatic power-off method for an electronic device having an input unit composed of a plurality of keys, the method comprising the steps of:
setting a time threshold;
counting a length of a duration of the key being continuously pressed;
comparing the length of the duration with the time threshold; and
turning off the electronic device when the length of the duration exceeds the time threshold.

2. The automatic power-off method of claim 1, wherein the length of the duration is about 3 seconds.

3. The automatic power-off method of claim 1, wherein the length of the duration is about 5 seconds.
